(19) United States
(12) Patent Application Publication
(10) Pub. No.: US 2005/0263073 A1
(43) Pub. Date: Dec. 1, 2005

(54) Furnace for heating a wafer and chemical vapor deposition apparatus having the same

(76) Inventors: Sung-Ho Kang, Gyeonggi-do (KR); Jae-Chul Lee, Gyeonggi-do (KR); Sang-Cheol Ha, Gyeonggi-do (KR); In-Pil Cha, Gyeonggi-do (KR); Duk-Young Jang, Gyeonggi-do (KR); Sung-Bum Park, Gyeonggi-do (KR); Cheol-Kyu Yang, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/123,783

(22) Filed: May 6, 2005

(30) Foreign Application Priority Data
Jun. 1, 2004 (KR) 2004-39682

(51) Int. Cl. C23C 16/00

(52) U.S. Cl. 118/725; 118/715

(57) ABSTRACT

A furnace for heating a wafer is provided comprising a process chamber including a space for processing a plurality of wafers. A heating member is disposed in the process chamber which generates a light and heat for heating the wafers. Moreover, a light blocking member is disposed in the process chamber for preventing the light from being transmitted onto the wafers but which permits the heat to be transmitted onto the wafers for heating the wafers. The furnace can be employed in an apparatus for chemical vapor deposition.

### CROSS REFERENCE TO RELATED APPLICATION

This application claims priority from Korean Patent Application No. 2004-39682 filed on Jun. 1, 2004, the contents of which are herein incorporated by reference in its entirety.

### BACKGROUND OF THE INVENTION

1. Field of the Invention

The present invention relates to a furnace for heating a wafer. More particularly, the present invention relates to a furnace for heating a wafer in a semiconductor manufacturing process, and to a chemical vapor deposition apparatus including the furnace.

2. Description of the Related Art

Semiconductor devices have been developed to have high response speeds, high reliability, a high degree of integration, etc. In general, a semiconductor device manufacturing process includes a deposition process for forming a layer on a wafer, an etching process for forming a predetermined pattern in the layer, a cleaning process for removing reaction by-products, etc.

The deposition process generally divided into a chemical vapor deposition process and a physical vapor deposition process. In the chemical vapor deposition process, gases provided in a process chamber are chemically reacted to form a layer on a wafer, after the wafer is positioned in the process chamber. Various processing conditions such as temperature, pressure and the flow rates of the reaction gases may affect the characteristics of the layer formed on the wafer in the chemical vapor deposition process. A low pressure chemical vapor deposition process is an example of a chemical vapor deposition process. In the low pressure chemical vapor deposition process, a process chamber has a pressure of from about 200 to about 700 mTorr while forming a layer on a wafer.

According to the chemical vapor deposition process, a layer having good uniformity and good step coverage may be formed on a wafer. In addition, a plurality of wafers may be simultaneously processed so that layers having good quality may be formed on the wafers. Recently, the chemical vapor deposition process has been widely employed for forming a polysilicon layer or an oxide layer on a wafer.

The above-mentioned conventional chemical vapor deposition process is carried out using a conventional chemical vapor deposition apparatus. The conventional chemical vapor deposition apparatus is generally divided into a vertical type chemical vapor deposition apparatus and a horizontal type chemical vapor deposition apparatus. The vertical type chemical vapor deposition apparatus is mainly used in the chemical vapor deposition process because it has a volume relatively smaller than that of the horizontal type chemical vapor deposition apparatus.

In the vertical type chemical vapor deposition apparatus, after reaction gases are provided into the chamber of the apparatus, at high temperature and under vacuum pressure, the reaction gases are chemically reacted to thereby form a layer on a wafer. The vertical type chemical vapor deposition apparatus includes a vertical type furnace that has a tube of quartz disposed within a heater. The vertical type furnace treats a plurality of wafers at the same time. Various deposition processes for forming polysilicon layers or oxide layers on wafers are performed using the conventional chemical vapor deposition apparatus having the vertical type furnace. In addition, a diffusion process for diffusing impurities into wafers is also carried out using the conventional chemical vapor deposition apparatus having the vertical type furnace.

Referring to FIG. 1, the conventional chemical vapor deposition apparatus 100 includes a process chamber 102, a heater 130, a manifold 110, a vacuum formation member 104, and a gas supply member 106.

The process chamber 102 includes an inner tube 112 and an outer tube 114. The inner tube 112 provides a space in which a boat 116 having wafers W is therein positioned. The boat 116 moves upwardly and downwardly within the inner tube 112.

The heater 130 provides a light and a heat for heating the wafers W within the inner tube 112. The heater 130 encloses the outer tube 114 of the process chamber 102. The manifold 110 supports the inner and the outer tubes 112 and 114 of the process chamber 102. The gas supply member 106 is connected to the process chamber 102 to provide predetermined gases into the space where the wafers W are positioned.

The vacuum formation member 104 controls the pressure within the process chamber 102 and also exhausts reaction by-products and unreacted gases from the process chamber 102. The vacuum formation member 104 includes a vacuum line 120 connected to the manifold 110, a main valve 122 installed in the vacuum line 120, and a vacuum pump 124 connected to the manifold through the manifold 110.

Referring to FIGS. 1 and 2, the heater 130 includes a coil enclosing the outer tube 114 of the process chamber 102. When an electric power is applied to the heater 130, light having a relatively long wavelength and heat are generated from the heater 130 because of the resistance of the heater 130. The heat and the light pass through the outer and the inner tubes 114 and 112, which can be formed of quartz, and reach the wafers W disposed within the inner tube 112, thereby heating the wafers W and the gases in that space.

However, when the light having the relatively long wavelength is irradiated onto the wafers W through the outer and the inner tubes 114 and 112 during deposition process, the layers may be abnormally formed on the wafers W and have an irregular thickness. In particular, when polysilicon layers are formed on the wafers W using the conventional heater 130, the polysilicon layers may have an extremely irregular thickness because of the above-described light transmission problem. Therefore, semiconductor devices which comprise these irregular polysilicon layers may have poor electrical characteristics.

### SUMMARY OF THE INVENTION

The present invention provides a furnace for heating a wafer that includes a heating member for generating a light and a heat, and a light blocking member for preventing the light from irradiating onto the wafer.

The present invention also provides a chemical vapor deposition apparatus including a heating member for generating a light and a heat, and a light blocking member for preventing the light from irradiating onto the wafer, thereby uniformly forming a layer on a wafer.

In accordance with one aspect of the present invention, a furnace for heating a wafer is provided. The furnace comprises a process chamber including a space for processing a plurality of wafers. It also includes a heating member disposed in the process chamber which generates a light and a heat for heating the wafers. A light blocking member is disposed in the process chamber for preventing the light from being transmitted onto the wafers but which permits the heat to be transmitted onto the wafers for heating the wafers.

Preferably, the process chamber further comprises an inner tube surrounding the wafers and an outer tube enclosing the inner tube. The inner tube typically has a substantially cylindrical shape and the outer tube has a substantially dome shape. Moreover, the inner and/or the outer tubes are preferably formed of quartz. The furnace preferably further comprises a manifold for supporting the inner tube and the outer tube, respectively. In addition, the inner tube and the outer tube are preferably vertically disposed on the manifold at a predetermined distance from each other. Preferably, the heating member is formed on a sidewall of the process chamber for enclosing the outer chamber.

Furthermore, the light blocking member may be disposed on the heating member.

Preferably, the light blocking member includes a layer coated on the heating member. In addition, the layer has a thickness of from about 1 mm, up to about 20 mm. The light blocking member is typically formed of asbestos or a ceramic material.

An apparatus for chemical vapor deposition is also provided. This apparatus comprises a process chamber and a heating member. These are the components of the furnace as described above. It also includes a light blocking member disposed in the process chamber for preventing the light from being transmitted onto the wafers in a deposition process for forming at least one layer on the wafers, but which permits the heat to be transmitted onto the wafers for heating the wafers. The layer on the wafers preferably comprises polysilicon.

A vacuum formation member is also included which is in communication with the process chamber. The vacuum formation member preferably comprises a vacuum line in communication with the process chamber, a vacuum pump in communication with the vacuum line, and a main valve disposed between the vacuum line and the vacuum pump.

More preferably, the main valve adjusts pressure within the process chamber during the deposition process, and the vacuum line exhausts particles formed during the deposition process.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a cross sectional view illustrating a conventional vertical furnace for heating a wafer;

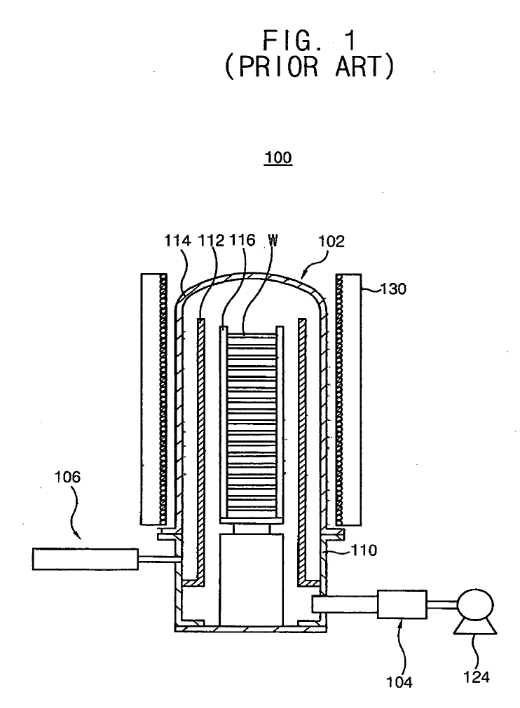

FIG. 2 is a picture illustrating the conventional vertical furnace for heating a wafer of FIG. 1;

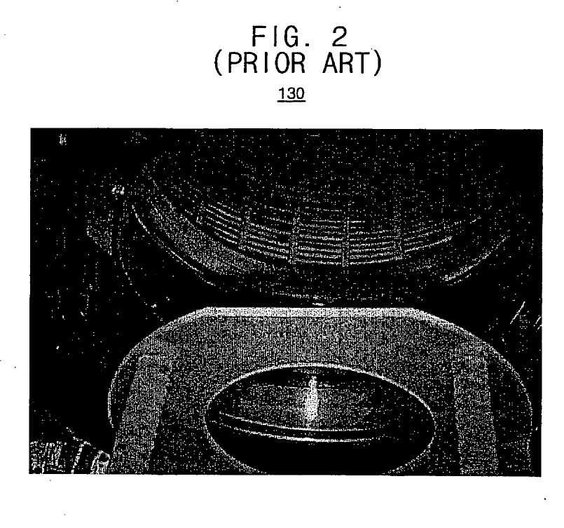

FIG. 3 is a cross sectional view illustrating a vertical furnace for heating a wafer in accordance with an exemplary embodiment of the present invention; and

FIG. 4 is a cross sectional view illustrating a chemical vapor deposition apparatus in accordance with an exemplary embodiment of the present invention.

### DETAILED DESCRIPTION OF THE INVENTION

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like reference numerals refer to similar or identical elements throughout. It will be understood that when an element such as a layer, region or wafer is referred to as being “on” or “onto” another element, it can be directly on the other element or intervening elements may also be present.

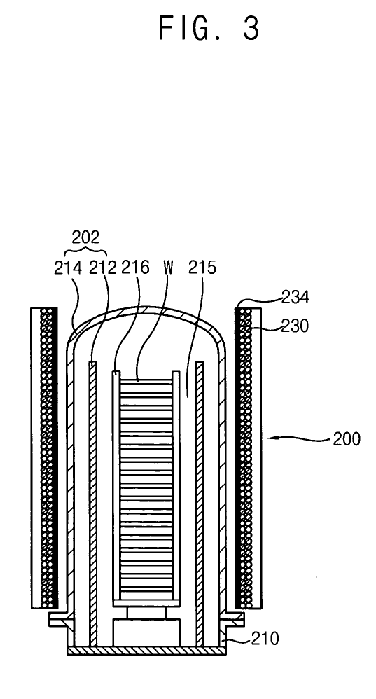

Referring to FIG. 3, a vertical furnace for heating a wafer 200 includes a process chamber 202, a manifold 210, a heating member 230 and a light blocking member 234.

A boat 216 having a plurality of wafers W loaded therein is placed in the process chamber 202. The manifold 210 supports the process chamber 202, and the heating member 230 provides a high temperature to the process chamber 202 to heat the wafers W loaded in the boat 216. The heating member 230 also heats reaction gases provided into the process chamber 202 in a deposition process for forming layers on the wafers W. The light blocking member 234 blocks light generated from the heating member 230 so that this light is not transmitted onto the wafers W.

The processing chamber 202 includes an inner tube 212 and an outer tube 214 which are respectively vertically disposed. The inner and the outer tubes 212 and 214 of the process chamber 202 may be formed of quartz. The inner tube 212 is separated from the outer tube 214 by a predetermined distance.

The inner tube 212 has a substantially cylindrical shape, and the outer tube 214 has a substantially dome shape that covers the inner tube 212. That is, the outer tube 214 encloses the inner tube 212.

The process chamber 202 further includes a space 215 in which the boat 216 including the wafers W is disposed. In particular, the space 215 is provided in the cylindrical inner tube 212.

The manifold 210 supports the inner and the outer tubes 212 and 214. After the wafers W are loaded in the boat 216, the boat 216 is loaded into the space 215 through the manifold 210. The boat 216 is upwardly transferred into the space 215 or downwardly carried out of the space 215 using a transfer member (not shown) such as an auto carrier or a robot arm.

The heating member 230 is disposed on a sidewall of the furnace 200. Particularly, the heating member 230 encloses the outer tube 214 of the process chamber 202 so that the heating member 230 heats the outer and the inner tubes 214 and 212 to a predetermined temperature. Thus, the space 215 provided in the inner tube 212 is heated to the predetermined temperature. The heating member 230 may have a coil structure that emits the heat and the light toward the space 215 where the wafers W are positioned. Here, an electrical power is applied to the heating member 230 to generate the high temperature and the light having a long wavelength from the heating member 230. A heating controller (not shown) is electrically connected to the heating member 230 to thereby control the heating member 230.

The light blocking member 234 may include a coated layer onto the heating member 230. Here, the layer may have a thickness of from about 1 mm, up to about 20 mm. The light blocking member 234 prevents the light generated in the heating member 230 from irradiating onto the wafers W positioned in the space 215. The light blocking member 234 may be formed of a light blocking material such as asbestos or a ceramic material so that the heat generated from the heating member 230 can be permeated by the light blocking member 234, and the light generated from the heating member 230 cannot be transmitted through the light blocking member 234. Therefore, the wafers W in the space 215 are heated by the heat generated from the heating member 230 through the light blocking member, but the light is not irradiated onto the wafers W due to the light blocking capability of the member 234.

If the light blocking member 234 is not disposed between the heating member 230 and the outer tube 214, the light generated from the heating member 230 passes through the outer and the inner tubes 214 and 212, and then is transmitted onto the wafers W positioned in the inner tube 212. When the light is irradiated onto the wafers W, the predetermined layers on the wafers W may be abnormally formed during the deposition process, such as during a chemical vapor deposition (CVD) process. Thus, the layers formed on the wafers W may have an irregular thickness which deteriorate the electrical characteristics of semiconductor devices. However, according to an aspect of the present invention, since the light blocking member 234 is formed on the heating member 230 having a heater (not shown), the light generated from the heating member 230 is not transmitted onto the layers formed on the wafers W in the deposition process, thereby improving the uniformity, and diminishing the irregularity, of the layers, and enhancing the electrical characteristics of the semiconductor devices thus produced.

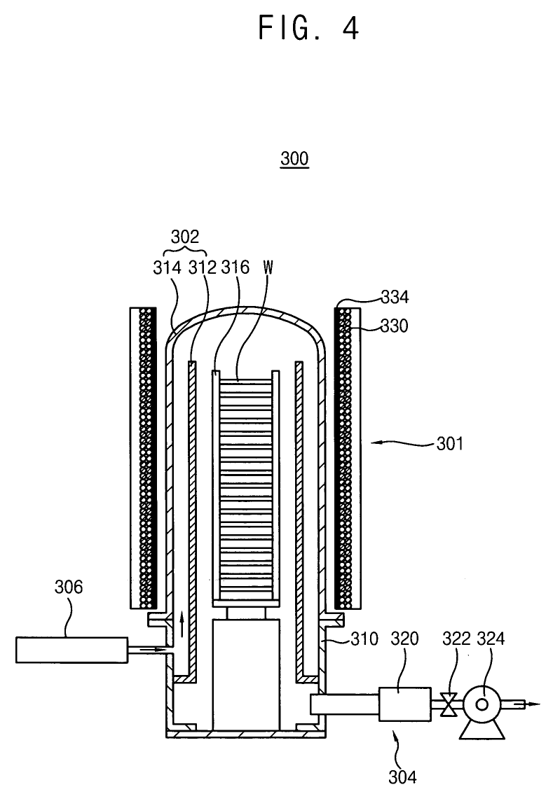

Referring to FIG. 4, a chemical vapor deposition apparatus 300 includes a furnace for heating a wafer 301, a vacuumizing member 304, a gas supply member 306, and a temperature measuring member (not shown).

As described above, the furnace 301 includes a process chamber 302 having an inner tube 312 and an outer tube 314 wherein a boat 316 having a plurality of wafers W therein is loaded. The furnace 301 further includes a manifold 310 for supporting the process chamber 302, a heating member 330 for heating the process chamber 302, and a light blocking member 334 for blocking a light generated from the heating member 330. The manifold 310 is positioned beneath the process chamber 310 to support the inner and the outer tubes 312 and 314. The heating member 330 is formed on an inside of a sidewall of the processing chamber 302, and the light blocking member 334 is positioned on the heating member 330.

The vacuum formation member 304 is connected to a lower portion of the process chamber 302, and the gas supply member 306 is connected to another lower portion of the process chamber 302. The temperature measuring member measures the temperature within the process chamber 302. The temperature measuring member may include a thermocouple.

The process chamber 302 may include a material having a high thermal conductivity such as quartz. The inner tube 312 and the outer tube 314 are vertically disposed with a predetermined distance. The inner tube 312 may have a substantially cylindrical shape. The outer tube 314 enclosing the inner tube 312 may have a substantially dome shape.

The vacuum formation member 304 adjusts the pressure within the process chamber 302. Additionally, the vacuum formation member 304 exhausts reaction by-products and unreacted gases from the process chamber 302 after completion of the deposition process for forming layers on the wafers W.

The vacuum formation member 304 includes a vacuum line 320, a main valve 322 and a vacuum pump 324. The vacuum line 320 is connected to the manifold 310, and the vacuum pump 324 is also connected to the manifold 310 through the vacuum line 320. The main valve 322 is disposed between the vacuum line 320 and the vacuum pump 324.

The main valve 322 adjusts the pressure within the process chamber 302 while performing the deposition process for forming the layers on the wafers W, for example, a polysilicon layer deposition process. Meanwhile, the main valve 322 is closed when a cleaning process is carried out about the process chamber 302 so that particles generated in the cleaning process may not be introduced into the vacuum pump 324. An outlet (not shown) is formed at one end portion of the vacuum line 320 so as to exhaust the particles resulting from the cleaning process. The outlet of the vacuum line 320 is opened in the cleaning process, and is closed in the deposition process for forming the layers on the wafers W.

The gas supply member 306 provides predetermined gases such as a source gas and/or a carrier gas into the process chamber 302. When polysilicon layers are formed on the wafers W, the gas supply member 306 provides a dichlorosilane (DCS; SiH₂Cl₂) gas and an ammonia (NH₃) gas into the process chamber 302. The gas supply member 306 further includes an air valve (not shown), and a mass flow meter (MFC) (not shown) to control a flow rate of the source gas and/or the carrier gas.

The wafers W are loaded in the boat 316, and then the boat 316 is transferred into the inner tube 312 of the process chamber 302 through the manifold 310. The boat 316 is upwardly transferred into the inner tube 312 or downwardly carried out of the inner tube 312 using a transfer member (not shown) such as an auto carrier or a robot arm.

The heating member 330 encloses the outer tube 314 of the process chamber 302 so that the heating member 330 heats the outer and the inner tubes 314 and 312 to a predetermined temperature for forming the layers on the wafers W. The heating member 330 may have a coil structure that emits heat and the light toward the inner tube 312 where the wafers W are processed. Electrical power may be applied to the heating member 330 to generate heat and light, having a predetermined wavelength, from the heating member 330. A heating controller (not shown) may be electrically connected to the heating member 330 to control the heating member 330.

In one exemplary embodiment of the present invention, the process chamber 302 is heated to have a temperature from about 500° C., up to about 1,000° C. in the process for forming the layers on the wafers W. In another exemplary embodiment of the present invention, the heating member 330 heats the process chamber 302 to a temperature of from about 800° C., up to about 1,200° C., in an oxidation process or a diffusion process.

The light blocking member 334 may include a layer coated on the heating member 330. The layer may have a thickness of from about 1 mm, up to about 20 mm. The light blocking member 334 prevents the light generated in the heating member 330 from irradiating onto the wafers W positioned in the inner tube 312. The light blocking member 334 may be formed of asbestos or a ceramic material so that the heat generated from the heating member 330 can permeate through the light blocking member 334, but the light generated from the heating member 330 cannot be transmitted through the light blocking member 334. Therefore, the wafers W in the inner tube 312 are heated by the heat from the heating member 330, but the light is not irradiated onto the wafers W due to the light blocking member 334.

If the light blocking member 334 may not disposed between the heating member 330 and the outer tube 314, the light generated from the heating member 330 passes through the outer and the inner tubes 314 and 312, and then is transmitted onto the wafers W positioned in the inner tube 312. When the light is irradiated onto the wafers W, the layers, for example polysilicon layers, may be abnormally formed on the wafers W in the deposition process. Hence, the layers formed on the wafers W may have an irregular thickness and will deteriorate the electrical characteristics of semiconductor devices. However, since the light blocking member 334 is formed on the heating member 330 having a heater (not shown), the light generated from the heating member 330 is not transmitted onto the layers formed on the wafers W in the deposition process, thereby improving the uniformity of the layers and enhancing the electrical characteristics of the semiconductor devices.

The temperature measuring member measures the temperature within the process chamber 302 in which the deposition process is carried out to thereby determine whether the deposition process is being performed at an appropriate temperature or not. The temperature measuring member vertically extends between the inner tube 312 and the outer tube 314 through the manifold 310.

Having described the exemplary embodiments of the present invention, it is noted that modifications and variations may be made by persons skilled in the art in light of the above teachings. It is therefore to be understood that changes may be made in the particular embodiment of the present invention disclosed which is within the scope and the spirit of the invention outlined by the appended claims.

1. a furnace for heating a wafer comprising:
a process chamber including a space for processing a plurality of wafers;
a heating member disposed in the process chamber, the heating member adapted to generate a light and a heat for heating the wafers; and
a light blocking member disposed in the process chamber to prevent the light from being transmitted onto the wafers but which permits the heat to be transmitted onto the wafers for heating the wafers.

2. The furnace of claim 1, wherein the process chamber further comprises an inner tube surrounding the wafers and an outer tube enclosing the inner tube.

3. The furnace of claim 2, wherein the inner tube has a substantially cylindrical shape and the outer tube has a substantially dome shape.

4. The furnace of claim 2, wherein the inner and/or the outer tubes are formed of quartz.

5. The furnace of claim 2, further comprising a manifold for supporting the inner tube and the outer tube.

6. The furnace of claim 5, wherein the inner tube and the outer tube are vertically disposed on the manifold at a predetermined distance from each other.

7. The furnace of claim 2, wherein the heating member is formed on a sidewall of the process chamber to enclose the outer chamber.

8. The furnace of claim 1, wherein the light blocking member is disposed on the heating member.

9. The furnace of claim 1, wherein the light blocking member includes a layer coated on the heating member.

10. The furnace of claim 8, wherein the layer has a thickness of from about 1 mm, up to about 20 mm.

11. The furnace of claim 1, wherein the light blocking member is formed of asbestos or a ceramic material.

12. An apparatus for chemical vapor deposition comprising:
a process chamber including a space for processing a plurality of wafers;
a vacuum formation member in communication with the process chamber;
a heating member disposed in the process chamber, the heating member adapted to generate a light and a heat for heating the wafers; and
a light blocking member disposed in the process chamber to prevent the light from being transmitted onto the wafers in a deposition process for forming at least one layer on the wafers, but which permits the heat to be transmitted onto the wafers for heating the wafers.

13. The chemical vapor deposition apparatus of claim 12, wherein the light blocking member is disposed on the heating member.

14. The chemical vapor deposition apparatus of claim 12, wherein the process chamber further comprises an inner tube surrounding said wafers and an outer tube enclosing the inner tube.

15. The chemical vapor deposition apparatus of claim 14, wherein the inner tube has a substantially cylindrical shape and the outer tube has a substantially dome shape.

16. The chemical vapor deposition apparatus of claim 12, wherein the light blocking member includes a layer coated on the heating member.

17. The chemical vapor deposition apparatus of claim 12, wherein the light blocking member comprises asbestos or a ceramic material.

18. The chemical vapor deposition apparatus of claim 12, wherein the layer comprises polysilicon.

19. The chemical vapor deposition apparatus of claim 12, wherein the vacuum formation member comprises a vacuum line in communication with the process chamber, a vacuum pump in communication with the vacuum line, and a main valve disposed between the vacuum line and the vacuum pump.

20. The chemical vapor deposition apparatus of claim 19, wherein the main valve adjusts pressure within the process chamber during the deposition process, and the vacuum line exhausts particles formed during the deposition process.
